(19) United States
(12) Patent Application Publication
(10) Pub. No.: US 2021/0392784 A1
(43) Pub. Date: Dec. 16, 2021

(54) HEAT DISSIPATING STRUCTURES AND ELECTRONIC CONTROL UNITS HAVING THE HEAT DISSIPATING STRUCTURES

(71) Applicant: DENSO International America, Inc., Southfield, MI (US)

(72) Inventors: Takuya MATSUYAMA, Novi, MI (US); Trevor STITELER, Rochester Hills, MI (US); Takehide OMURA, West Bloomfield Township, MI (US)

(21) Appl. No.: 17/191,867

(22) Filed: Mar. 4, 2021

Related U.S. Application Data
(60) Provisional application No. 63/038,422, filed on Jun. 12, 2020.

(51) Int. Cl. H05K 7/20; H01L 23/367

(52) U.S. Cl. CPC H05K 7/20409; H01L 23/3672

(57) ABSTRACT

A heat dissipating structure includes a heat sink having a top surface and an opposing bottom surface. The heat dissipating structure further includes an insulating layer attached to the top surface of the heat sink. The heat dissipating structure also includes a wiring pattern disposed directly on the insulating layer. The heat dissipating structure further includes at least one heat-generating electronic component connected to the wiring pattern. An electronic control unit includes a heat dissipating structure having a heat sink and at least one heat-generating electronic component thermally coupled to the heat sink, and a print circuit board (PCB) located spaced from the top surface of the heat sink such that an air gap exists therebetween.

### CROSS-REFERENCE TO RELATED APPLICATION

This application claims the benefit and priority of U.S. Provisional Application No. 63/038,422, filed on Jun. 12, 2020, the disclosure of which is incorporated in its entirety by reference herein.

### TECHNICAL FIELD

The present disclosure relates to heat dissipating structures and electronic control units (ECUs) having the heat dissipating structures.

### BACKGROUND

There is an ever-increasing demand to reduce the size of an ECU such that the size of packaging can also be reduced. One way to achieve this purpose is to implement smaller electronic components or elements in the ECU. However, since small electronic components normally have small heat dissipation areas, a heat dissipating structure is needed to help release the heat generated by the electronic components or elements.

### SUMMARY

According to one embodiment, a heat dissipating structure is disclosed. The heat dissipating structure may include a heat sink having a top surface and an opposing bottom surface. The heat dissipating structure may further include an insulating layer attached to the top surface of the heat sink. The heat dissipating structure may also include a wiring pattern disposed directly on the insulating layer. The heat dissipating structure may further include at least one heat-generating electronic component connected to the wiring pattern.

According to another embodiment, a heat dissipating structure is disclosed. The heat dissipating structure may include a heat sink having a top surface and an opposing bottom surface. The heat dissipating structure may further include a wiring pattern disposed directly on the top surface of the heat sink. The heat dissipating structure may also include at least one heat-generating electronic component connected to the wiring pattern.

According to yet another embodiment, an electronic control unit (ECU) is disclosed. The ECU may include a heat dissipating structure. The heat dissipating structure may further include a heat sink and at least one heat-generating electronic component thermally coupled to the heat sink. The heat sink may include a top surface and an opposing bottom surface. The ECU may further include a print circuit board (PCB) located spaced from the top surface of the heat sink such that an air gap exists therebetween.

### BRIEF DESCRIPTION OF THE DRAWINGS

FIG. 1A depicts a schematic side view of a conventional electronic control unit (ECU).

FIG. 1B depicts a schematic top view of the conventional ECU as described in FIG. 1A.

FIG. 2A depicts a schematic side view of a first embodiment of a heat dissipating structure according to the present disclosure.

FIG. 2B depicts a schematic top view of the first embodiment of the heat dissipating structure as described in FIG. 2A.

FIG. 3A depicts a schematic side view of a second embodiment of a heat dissipating structure according to the present disclosure.

FIG. 3B depicts a schematic top view of the second embodiment of the heat dissipating structure as described in FIG. 3A.

FIG. 4 depicts a schematic side view of a first embodiment of an ECU according to the present disclosure.

FIG. 5 depicts a schematic side view of a second embodiment of an ECU according to the present disclosure.

FIG. 6 depicts a schematic diagram illustrating a general process of photolithography.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

This disclosure should not be limited to the specific embodiments and methods described below, as specific components and/or conditions may, of course, vary. Furthermore, the terminology used herein is used only for the purpose of describing embodiments of the present disclosure and is not intended to be limiting in any way.

As used in the specification and the appended claims, the singular form “a,” “an,” and “the” comprise plural referents unless the context clearly indicates otherwise. For example, reference to a component in the singular is intended to comprise a plurality of components.

The first definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

Reference is being made in detail to compositions, embodiments, and methods of embodiments known to the inventors. However, disclosed embodiments are merely exemplary, and the scope of the disclosure may be embodied in various and alternative forms. Therefore, specific details disclosed herein are not to be interpreted as limiting, rather merely as representative bases for teaching one skilled in the art to variously employ the present disclosure.

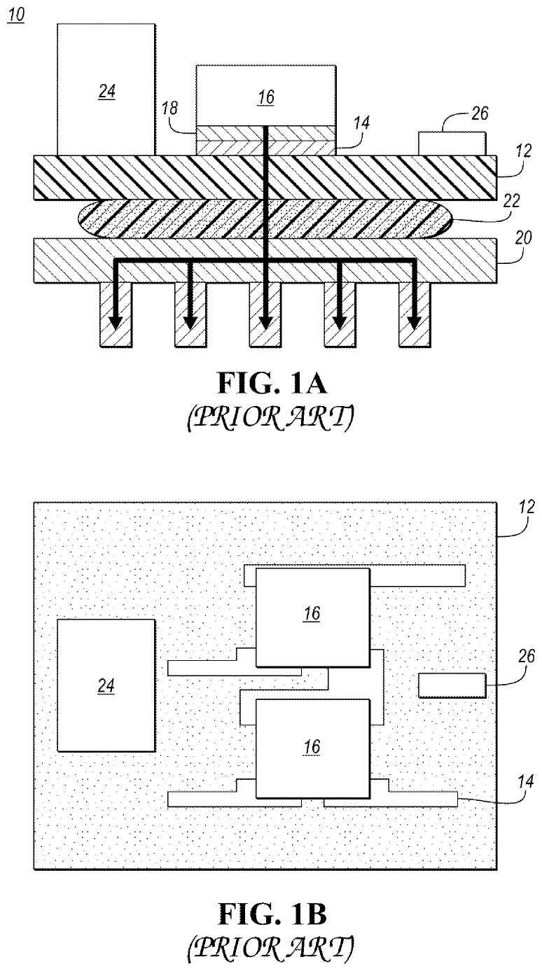

FIG. 1A depicts a schematic side view of a conventional ECU 10. Referring to FIG. 1A, the ECU 10 may include a PCB 12 and a wiring layer 14 formed on a top surface of the PCB 12. The ECU 10 may further include at least one electronic component 16 connected to the wiring layer 14. The at least one electronic component 16 may be soldered or the like (indicated by 18) to the wiring layer 14. The at least one electronic component 16 may be a heat-generating electronic component, such as a metal-oxide-semiconductor field-effect transistor (MOSFET). To dissipate heat generated by the at least one electronic component 16 during an operation of the ECU 10, the ECU 10 may further include a heat sink 20 thermally coupled to a bottom surface of the PCB 12 through a thermal conductive layer 22. That is, the thermal conductive layer 22 is situated between the PCB 12 and the heat sink 20. The thermal conductive layer 22 may include a thermal interface material (TIM), such as a thermal paste, a thermal adhesive, or a thermal tape. The heat sink 20 may be electrically conductive. Therefore, a heat dissipating path, indicated by the arrows, is created between the at least one electronic component 16 and the heat sink 20 such that heat generated by the at least one electronic component 16 can be released to the heat sink 20 and then removed from the heat sink 20.

As shown in FIG. 1A, the ECU may further include other electronic elements, for example, 24 and 26, in addition to the at least one electronic component 16. These other electronic elements may be directly connected to the top surface of the PCB 12. These other electronic elements may be non-heat-generating or low heat-generating electronic elements. These other electronic components may be resistors, capacitors, or low heat-generating transistors.

FIG. 1B depicts a schematic top view of the conventional ECU 10 as described in FIG. 1A. As shown in FIG. 1B, the at least one electronic component 16 of the ECU 10 may be connected to the PCB 12 through the wiring layer 14 formed on the top surface of the PCB 12. In addition, other electronic elements, such as 24 and 26, may be directly connected to the top surface of the PCB 12. These other electronic elements may be non-heat-generating or low heat-generating electronic elements.

Although the heat dissipating path created between the at least one electronic component 16 and the heat sink 20, as depicted in FIG. 1A, can facilitate heat dissipation from the at least one electronic component 16 to the heat sink 20, such a heat dissipating path may not be ideal, because to remove the heat generated by the at least one electronic component 16 from the ECU 10, the heat needs to pass through the PCB 12 and the thermal conductive layer 22 before it arrives at the heat sink 20. Such a long heat dissipating path may, necessarily, increase the size of the ECU 10.

Aspects of the present disclosure relates to heat dissipating structures and ECUs having the heat dissipating structures. In one embodiment, the present disclosure relates to a heat dissipating structure which includes a heat sink having a top surface and an opposing bottom surface, an insulating layer attached to the top surface of the heat sink, a wiring pattern disposed directly on the insulating layer, and at least one heat-generating electronic component connected to the wiring pattern. In another embodiment, the present disclosure relates to a heat dissipating structure which includes a heat sink having a top surface and an opposing bottom surface, a wiring pattern disposed directly on the top surface of the heat sink, and at least one heat-generating electronic component connected to the wiring pattern. In yet another embodiment, the present disclosure relates to an ECU which includes a heat dissipating structure having a heat sink and at least one heat-generating electronic component thermally coupled to the heat sink, and a print circuit board (PCB) located spaced from the top surface of the heat sink such that an air gap exists therebetween.

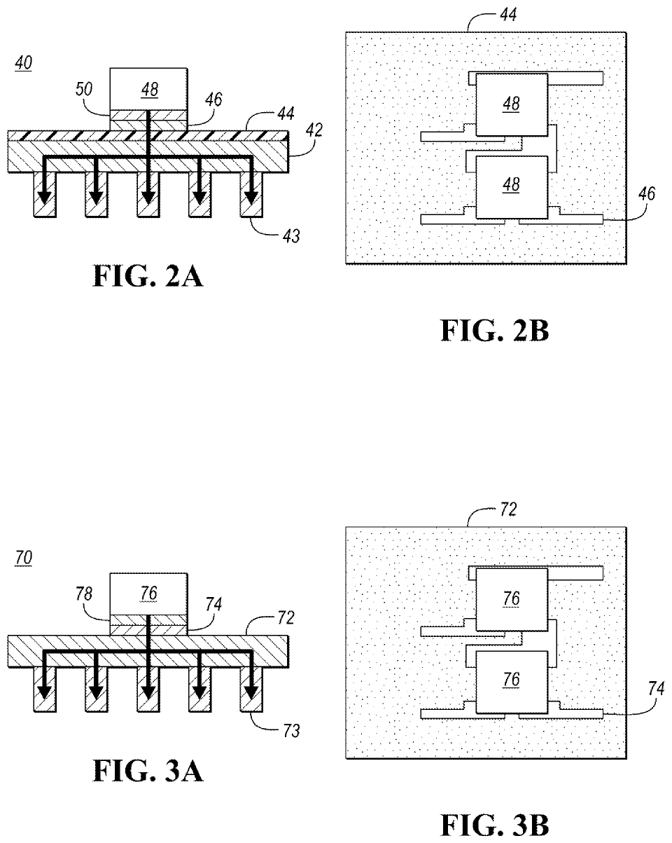

FIG. 2A depicts a schematic side view of a first embodiment of a heat dissipating structure 40 according to the present disclosure. The heat dissipating structure 40 may be used in an ECU. As shown in FIG. 2A, the heat dissipating structure 40 may include a heat sink 42 having a top surface and an opposing bottom surface. The heat dissipating structure 40 may further include an insulating layer 44 attached to the top surface of the heat sink 42. The heat sink 42 may be electrically conductive. The heat sink 42 may include fins 43 configured to facilitate in heat transfer. The insulating layer 44 may be electrically insulating and thermally conductive. In some embodiments, the insulating layer 44 may include boron nitride or a heat conductive polymer.

Referring to FIG. 2A, a wiring pattern 46 may be directly formed on the insulating layer 44. In some embodiments, the wiring pattern 46 is photolithographically disposed on the insulating layer 44 based on a photolithography technology. Photolithography is a process of creating a pattern on a thin film of a material applied to a substrate. The process uses light to transfer the pattern of a photomask from the photomask to the thin film of the material applied to the substrate. As such, by directly disposing the wiring pattern 46 on the insulating layer 44, a bonding material, such as the thermal conductive layer 22 of FIG. 1A, a circuit substrate, or the like that is commonly used to connect two electrical parts in an ECU (e.g. between a wiring pattern and a PCB, or between a PCB and a heat sink) can be avoided.

Furthermore, at least one electronic component 48 may be connected to the wiring pattern 46. The at least one electronic component 48 is thermally coupled to the heat sink 42. In some embodiments, the at least one electronic component 48 is soldered or like (indicated by 50) to the wiring pattern 46. The at least one electronic component 48 may be a heat-generating electronic component, including, but not limited to, a heat-generating transistor, a current limiting resistor, and a power diode. The heat-generating transistor may further include, but not limited to, a MOSFET, a bipolar junction transistor (BJT), a junction field-effect transistor (JFET), and an insulated-gate bipolar transistor (IGBT).

In FIG. 2A, during an operation of the ECU, heat generated by the at least one electronic component 48 may be quickly released to the heat sink 42 and subsequently removed from the ECU, without the need of traveling through the PCB 12 and the additional thermal conductive layer 22 as required in the conventional ECU 10 in FIG. 1A. Therefore, the compact heat dissipating structure of FIG. 2A may not only improve the heat dissipating capability of the at least one electronic component but also reduce the size of the ECU.

FIG. 2B depicts a schematic top view of the first embodiment of the heat dissipating structure 40 as described in FIG. 2A. Referring to FIG. 2B, the wiring pattern 46 may be photolithographically disposed on the insulating layer 44 which is attached to the top surface of the heat sink (42 in FIG. 2A). At least one electronic component 48 may be connected to the wiring pattern 46, for example, by soldering or the like.

FIG. 3A depicts a schematic side view of a second embodiment of a heat dissipating structure 70 according to the present disclosure. The heat dissipating structure 70 may be used in an ECU. The heat dissipating structure 70 may include a heat sink 72 having a top surface and an opposing bottom surface. The heat sink 72 may be electrically non-conductive. The heat sink 72 may include fins 73 configured to facilitate in heat transfer.

As shown in FIG. 3A, a wiring pattern 74 may be directly formed on the top surface of the heat sink 72. In some embodiments, the wiring pattern 74 is photolithographically disposed on the top surface of the heat sink 72 based on a photolithography technology as described in FIG. 2A. By directly disposing the wiring pattern 74 on the top surface of the heat sink 72, a bonding material, such as the thermal conductive layer 22 of FIG. 1A, a circuit substrate, or the like that is commonly used to connect two electrical parts in an ECU (e.g. between a wiring pattern and a PCB, or between a PCB and a heat sink) can be avoided.

Furthermore, at least one electronic component 76 may be connected to the wiring pattern 74. The at least one electronic component 76 is thermally coupled to the heat sink 72. In some embodiments, the at least one electronic component 76 is soldered or the like (indicated by 78) to the wiring pattern 74. The at least one electronic component 76 may be a heat-generating electronic component, including, but not limited to, a heat-generating transistor, a current limiting resistor, and a power diode. The heat-generating transistor may further include, but not limited to, a MOSFET, a BJT, a JFET, and an IGBT.

In FIG. 3A, during an operation of the ECU, heat generated by the at least one electronic component 76 may be quickly released to the heat sink 72 and then removed from the ECU, without the need of traveling through the PCB 12 and the additional thermal conductive layer 22 as required in the conventional ECU 10 in FIG. 1A nor the need of traveling through the insulating layer 44 as described in FIG. 2A. Therefore, the heat dissipating structure 70 of FIG. 3A may further improve the heat dissipating capability of the at least one electronic component of the ECU and further reduce the size of the ECU.

FIG. 3B depicts a schematic top view of the second embodiment of the heat dissipating structure 70 as described in FIG. 3A. Referring to FIG. 3B, the wiring pattern 74 may be photolithographically disposed on the top surface of the heat sink 72. At least one electronic component 76 may be connected to the wiring pattern 74, for example, by soldering or the like.

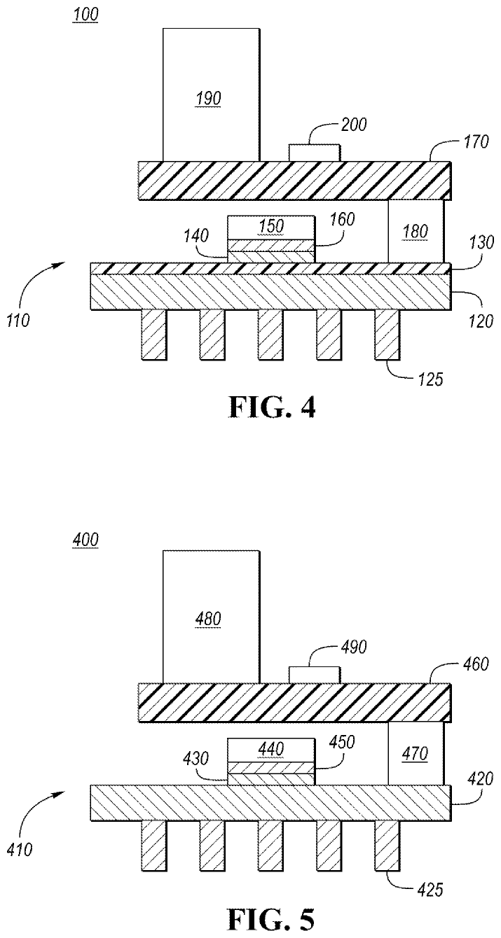

FIG. 4 depicts a schematic side view of a first embodiment of an ECU 100 according to the present disclosure. The ECU 100 may include the heat dissipating structure 40 of FIGS. 2A and 2B as described above. As shown in FIG. 4, the ECU 100 may include a heat dissipating structure 110 having a heat sink 120 and an insulating layer 130 attached to a top surface of the heat sink 120. The heat sink 120 also includes a bottom surface opposite to the top surface thereof. The heat sink 120 may be electrically conductive. The heat sink 120 may include fins 125 configured to facilitate in heat transfer. The insulating layer 130 may be electrically insulating and thermally conductive. In some embodiments, the insulating layer 130 may include boron nitride or a heat conductive polymer.

Referring to FIG. 4, a wiring pattern 140 may be directly formed on the insulating layer 130. In some embodiments, the wiring pattern 140 is photolithographically disposed on the insulating layer 130 based on a photolithography technology as described in FIG. 2A. By directly disposing the wiring pattern 140 on the insulating layer 130, a bonding material, such as the thermal conductive layer 22 of FIG. 1A, a circuit substrate, or the like that is commonly used to connect two electrical parts in an ECU (e.g. between a wiring pattern and a PCB, or between a PCB and a heat sink) can be avoided.

Furthermore, at least one electronic component 150 may be connected to the wiring pattern 140. The at least one electronic component 150 is thermally coupled to the heat sink 120. In some embodiments, the at least one electronic component 150 is soldered or the like (indicated by 160) to the wiring pattern 140. The at least one electronic component 150 may be a heat-generating electronic component, including, but not limited to, a heat-generating transistor, a current limiting resistor, and a power diode. The heat-generating transistor may further include, but not limited to, a MOSFET, a BJT, a JFET, and an IGBT.

Still referring to FIG. 4, the ECU 100 may further include a PCB 170 separated from and connected to the heat dissipating structure 110 via a connector 180. As shown in the illustrated embodiment, the connector 180 may support the PCB 170 in an elevated or spaced relation from the heat dissipating structure 110, such as the electronic component 150, the insulating layer 130, the heat sink 120, etc. The connector 180 may be electrically conductive. The connector 180 may include an electrically conductive material. The electrically conductive material may include, but not limited to, brass, phosphor bronze, and beryllium copper. The connector 180 may be a pillar, rod, or the like that maintains the PCB spaced from the heat sink 120.

In the illustration of FIG. 4, the connector 180 is shown directly connecting the PCB 170 to the insulating layer 130. However, it should be understood that in some other embodiments, additional materials or components are located at the interface between the connector 180 and the PCB 170, or between the connector 180 and the insulating layer 130. In yet some other embodiments, the connector 180 connects the PCB 170 to the wiring pattern 140 that is directly disposed on the insulating layer 130. In still some other embodiments, the connector 180 connects directly to the heat sink 120.

As shown in FIG. 4, the ECU 100 may also include at least one electronic element, such as 190 and 200, directly connected to the PCB 170. The at least one electronic element may be non-heat-generating, including, but not limited to, resistors and capacitors. The at least one electronic element may also be low heat-generating electronic elements, including, but not limited to, low heat-generating transistors.

In FIG. 4, during an operation of the ECU 100, heat generated by the at least one electronic component 150 may be quickly released to the heat sink 120 and subsequently removed from the ECU 100 (as indicated by the arrows in FIG. 2A), without first traveling through the PCB 170. In other words, the PCB 170 is not in the direct path of heat transfer. It can therefore be said that, in some embodiments, a PCB does not exist directly adjacent to (i.e., does not touch) any of the heat-generating electronic component (e.g. MOSFET) 150, the wiring pattern 140, the insulating layer 130, or the heat sink 120. Instead, the PCB 170 is positioned in an elevated or spaced relation from those components and not in the path of the heat transfer from the heat-generating electronic component (e.g. MOSFET) 150 to the heat sink 120. An air gap exists between the PCB 170 and the heat sink 120.

FIG. 5 depicts a schematic side view of a second embodiment of an ECU 400 according to the present disclosure. The ECU 400 may include the heat dissipating structure 70 of FIGS. 3A and 3B as described above. As shown in FIG. 5, the ECU 400 may include a heat dissipating structure 410 having a heat sink 420. The heat sink 420 includes a top surface and an opposing bottom surface. The heat sink 420 may be electrically non-conductive. The heat sink 420 may include fins 425 configured to facilitate in heat transfer.

As shown in FIG. 5, a wiring pattern 430 may be directly formed on the top surface of the heat sink 420. In some embodiments, the wiring pattern 430 is photolithographically disposed on the top surface of the heat sink 420 based on a photolithography technology as described in FIG. 2A. By directly disposing the wiring pattern 430 on the top surface of the heat sink 420, a bonding material, such as the thermal conductive layer 22 of FIG. 1A, a circuit substrate, or the like that is commonly used to connect two electrical parts in an ECU (e.g. between a wiring pattern and a PCB, or between a PCB and a heat sink) can be avoided.

Furthermore, at least one electronic component 440 may be connected to the wiring pattern 430. The at least one electronic component 440 is thermally coupled to the heat sink 420. In some embodiments, the at least one electronic component 440 is soldered or the like (indicated by 450) to the wiring pattern 430. The at least one electronic component 440 may be a heat-generating electronic component, including, but not limited to, a heat-generating transistor, a current limiting resistor, and a power diode. The heat-generating transistor may further include, but not limited to, a MOSFET, a BJT, a JFET, and an IGBT.

Still referring to FIG. 5, the ECU 400 may further include a PCB 460 separated from and connected to the heat dissipating structure 410 of the ECU 400 via a connector 470. As shown in the illustrated embodiment, the connector 470 may support the PCB 460 in an elevated or spaced relation from the heat dissipating structure 410, such as the electronic component 440, the heat sink 420, etc. The connector 470 may be electrically conductive. The connector 470 may include an electrically conductive material. The electrically conductive material may include, but not limited to, brass, phosphor bronze, and beryllium copper. The connector 470 may be a pillar, rod, or the like that maintains the PCB spaced from the heat sink 420.

In the illustration of FIG. 5, the connector 470 is shown directly connecting the PCB 460 to the heat sink 420. However, it should be understood that in some other embodiments, additional materials or components are located at the interface between the connector 470 and the PCB 460, or between the connector 470 and the heat sink 420. In yet some other embodiments, the connector 470 connects the PCB 460 to the wiring pattern 430 that is directly disposed on the heat sink 420.

As shown in FIG. 5, the ECU may also include at least one electronic element, such as 480 and 490, directly connected to the PCB 460. The at least one electronic element may be non-heat-generating, including, but not limited to, resistors and capacitors. The at least one electronic element may also be low heat-generating electronic elements, including, but not limited to, low heat-generating transistors.

In FIG. 5, during an operation of the ECU 400, heat generated by the at least one electronic component 440 may be quickly released to the heat sink 420 and subsequently removed from the ECU 400 (as indicated by the arrows in FIG. 3A), without first traveling through the PCB 460. In other words, the PCB 460 is not in the direct path of heat transfer. It can therefore be said that, in some embodiments, a PCB does not exist directly adjacent to (i.e., does not touch) any of the heat-generating electronic component (e.g. MOSFET) 440, the wiring pattern 430, or the heat sink 420. Instead, the PCB 460 is positioned in an elevated or spaced relation from those components and not in the path of the heat transfer from the heat-generating electronic component (e.g. MOSFET) 440 to the heat sink 420. An air gap exists between the PCB 460 and the heat sink 420.

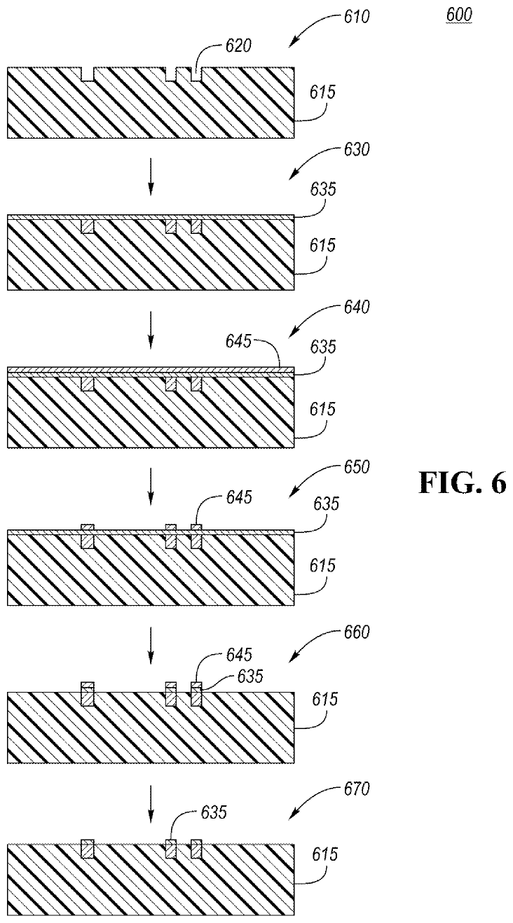

FIG. 6 depicts a schematic diagram illustrating a general process of photolithography 600. In some embodiments, the general process of photolithography 600 may be used to dispose a wiring pattern directly onto an insulating layer, which can then be attached to a surface of an electrically conductive heat sink as described in FIGS. 2A and 4. In some other embodiments, the general process of photolithography 600 may be used to disposes a wiring pattern directly onto an electrically non-conductive heat sink as described in FIGS. 3A and 5.

Referring to FIG. 6, at step 610, a substrate 615 is provided using injection molding. The substrate 615 may include indents 620 on one surface thereof. In one embodiment, the substrate 615 may be an insulating layer, i.e., the indents 620 are formed on one surface of the insulating layer. The insulating layer with the indents 620 may then be applied onto a surface of an electrically conductive heat sink. In another embodiment, the substrate 615 may be an electrically non-conductive heat sink, i.e., the indents 620 are disposed on one surface of the heat sink.

Still referring to FIG. 6, at step 630, a thin film of a material 635 is deposited onto the surface of the substrate 615 having the indents 620. The material 635 may be copper. The material 635 may be deposited onto the surface of the substrate 615 using a deposition method, including, but not limited to, electroplating, electroless plating, chemical vapor deposition, and physical vapor deposition. After the deposition of the material 635, the indents 620 of the substrate 615 are filled with the material 635. At step 640, photoresist 645 is applied onto the material 635. At step 650, photoresist 645 is exposed to a light source (not shown). A photomask (not shown) is used to transfer a pattern of the photomask onto the photoresist 645. The pattern of the photomask is designed to be spatially aligned with each indent 620 of the substrate 615. The light source may be ultraviolet (UV) light. After light exposure, some of the photoresist 645 is removed from the material 635, thereby exposing some of the material 635. Photoresist 645 that corresponds to the location of each indent 620 remains on the material 635. At step 660, an etching solution is applied to remove the exposed material 635. The etching solution may be nitric acid. At step 670, the remaining photoresist 645, i.e., the photoresist located corresponding to the location of each indent 620, is removed, leaving material 635 on the substrate 615. In some embodiments, the material 635 disposed into the indents 620 of the substrate 615 forms a wiring pattern.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the present disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat dissipating structure comprising:
a heat sink having a top surface and an opposing bottom surface;
an insulating layer attached to the top surface of the heat sink;
a wiring pattern disposed directly on the insulating layer; and
at least one heat-generating electronic component connected to the wiring pattern.

2. The heat dissipating structure of claim 1, wherein the insulating layer includes boron nitride or a heat conductive polymer.

3. The heat dissipating structure of claim 1, wherein the at least one heat-generating electronic component is a heat-generating transistor, a current limiting resistor, or a power diode.

4. The heat dissipating structure of claim 3, wherein the heat-generating transistor is a metal-oxide-semiconductor field-effect transistor (MOSFET), a bipolar junction transistor (BJT), a junction field-effect transistor (JFET), or an insulated-gate bipolar transistor (IGBT).

5. A heat dissipating structure comprising:
a heat sink having a top surface and an opposing bottom surface;
a wiring pattern disposed directly on the top surface of the heat sink; and
at least one heat-generating electronic component connected to the wiring pattern.

6. The heat dissipating structure of claim 5, wherein the at least one heat-generating electronic component is a heat-generating transistor, a current limiting resistor, or a power diode.

7. The heat dissipating structure of claim 6, wherein the heat-generating transistor is a metal-oxide-semiconductor field-effect transistor (MOSFET), a bipolar junction transistor (BJT), a junction field-effect transistor (JFET), or an insulated-gate bipolar transistor (IGBT).

8. An electronic control unit (ECU) comprising:
a heat dissipating structure having a heat sink and at least one heat-generating electronic component thermally coupled to the heat sink, the heat sink having a top surface and an opposing bottom surface; and
a print circuit board (PCB) located spaced from the top surface of the heat sink such that an air gap exists therebetween.

9. The ECU of claim 8, wherein the at least one heat-generating electronic component is a heat-generating transistor, a current limiting resistor, or a power diode.

10. The ECU of claim 8, wherein the heat dissipating structure further comprises:
an insulating layer attached to the top surface of the heat sink; and
a wiring pattern disposed directly on the insulating layer, the at least one heat-generating electronic component connected to the wiring pattern,
wherein heat generated from the at least one heat-generating electronic component is configured to travel through the insulating layer and into the heat sink without first traveling through the PCB.

11. The ECU of claim 10, wherein the insulating layer includes boron nitride or a heat conductive polymer.

12. The ECU of claim 10, further comprising a connector connecting the PCB to the insulating layer while maintaining the PCB spaced from the insulating layer.

13. The ECU of claim 12, wherein the connector includes an electrically conductive material.

14. The ECU of claim 13, wherein the electrically conductive material is brass, phosphor bronze, or beryllium copper.

15. The ECU of claim 8, wherein the heat dissipating structure further comprises a wiring pattern disposed directly on the top surface of the heat sink, the at least one heat-generating electronic component connected to the wiring pattern,
wherein heat generated from the at least one heat-generating electronic component is configured to travel to the heat sink without first traveling through the PCB.

16. The ECU of claim 15, further comprising a connector connecting the PCB to the heat sink while maintaining the PCB spaced from the heat sink.

17. The ECU of claim 16, wherein the connector includes an electrically conductive material.

18. The ECU of claim 17, wherein the electrically conductive material is brass, phosphor bronze, or beryllium copper.

19. The ECU of claim 8, wherein the ECU further comprises at least one electronic element directly connected to the PCB.

20. The ECU of claim 19, wherein the at least one electronic element is non-heat-generating or low heat-generating electronic element.
